(19) United States
(12) Patent Application Publication
(10) Pub. No.: US 2006/0215365 A1
(43) Pub. Date: Sep. 28, 2006

(54) Monitor heat dissipator

(75) Inventor: Ming-Chien Kuo, Shulin City (TW)

Correspondence Address: BACON & THOMAS, PLLC, 625 SLATERS LANE, FOURTH FLOOR, ALEXANDRIA, VA, 22314, US

(73) Assignee: COOLER MASTER CO., LTD., Chung-Ho City (TW)

(21) Appl. No.: 11/372,109

(22) Filed: Mar. 10, 2006

(30) Foreign Application Priority Data
Mar. 24, 2005 (TW) 094204568

(51) Int. Cl. H05K 7/20; G06F 1/20

(52) U.S. Cl. 361/697; 361/687

(57) ABSTRACT

A monitor heat dissipator includes a heat conductive plate having a first path defined in a top portion of the heat conductive plate and a second path defined in a bottom portion of the heat conductive plate to be in communication with the first path. A fluid is received in the second path to flow to the first path from the second path. A heat exchange assembly has a connecting tube in communication with the first path and the second path so that excessive heat carried by the fluid which flows from the second path to the first path is dissipated by the heat exchange assembly.

### BACKGROUND OF THE INVENTION

1. Field of the Invention

The present invention relates to a heat dissipator, and more particularly to a monitor heat dissipator to effectively dissipate heat from the monitor to maintain operation of the monitor.

2. Description of the Prior Art

Currently, displays have been shifted from bulky and heavy-weighted type to light weight and high resolution displays. In recent years, liquid crystal displays (LCD) have been popular in the market and will replace the traditional CRT monitor because the LCD monitor is portable and produces high quality images. However, when the LCD monitor is in use, it produces tremendous heat, which somehow influences the images. That is, when the LCD monitor is producing heat due to normal operation, the heat coming out from the back of the monitor distorts the images and damages electronic elements inside the monitor. As a result, the life span of the LCD monitor is shortened if the problem caused by the heat is not solved.

To overcome the shortcomings, the present invention tends to provide an improved heat dissipator to mitigate the aforementioned problems.

### SUMMARY OF THE INVENTION

The primary objective of the present invention is to provide an improved heat dissipator to effectively dissipate heat from the LCD monitor so as to allow the LCD monitor to work properly.

Other objects, advantages and novel features of the invention will become more apparent from the following detailed description when taken in conjunction with the accompanying drawings.

### BRIEF DESCRIPTION OF THE DRAWINGS

FIG. 1 is a cross sectional view showing the internal structure of a heat conductive plate of the heat dissipator of the present invention;

FIG. 2 is a cross sectional view showing that the heat conductive plate is associated with a heat exchange assembly;

FIG. 3 is a top plan view showing that the heat conductive plate is composed of two halves; and

FIG. 4 is a schematic side plan view showing that the heat dissipator of the present invention is attached to a back of a monitor to effectively dissipate heat generated by the monitor.

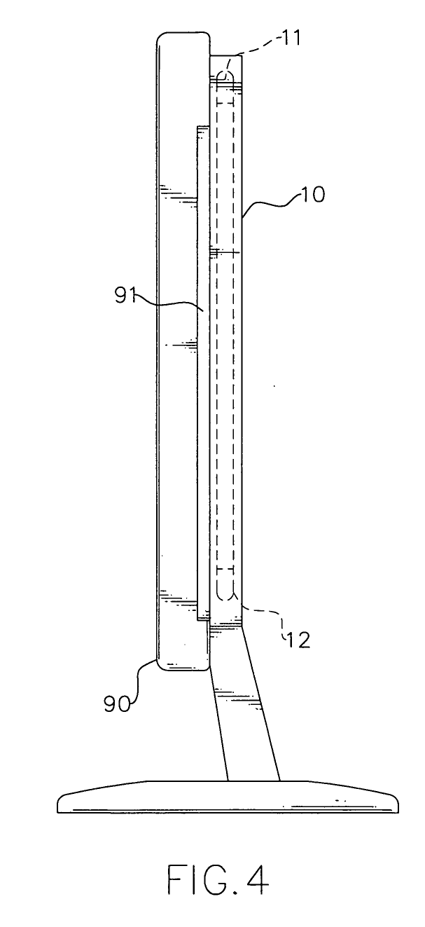

### DETAILED DESCRIPTION OF THE PREFERRED EMBODIMENT

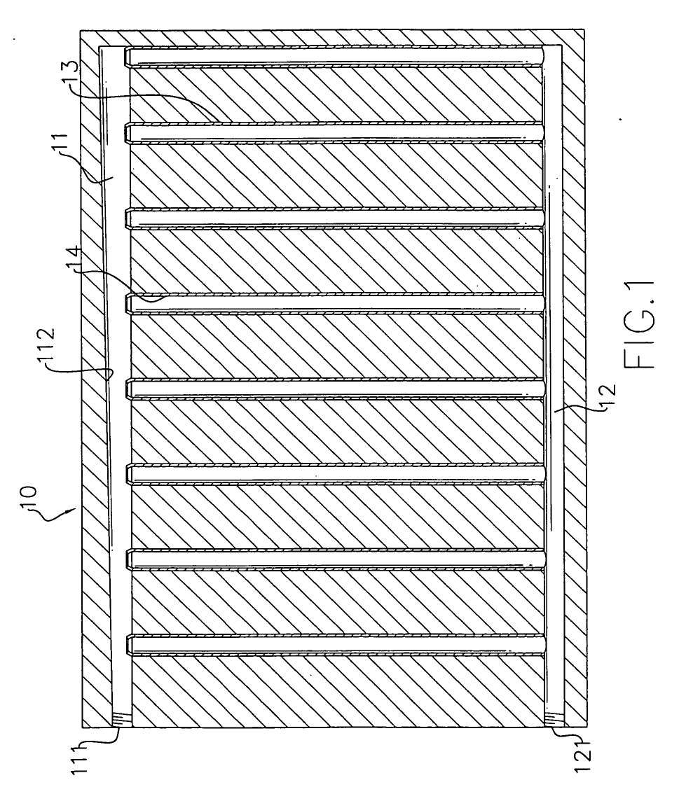

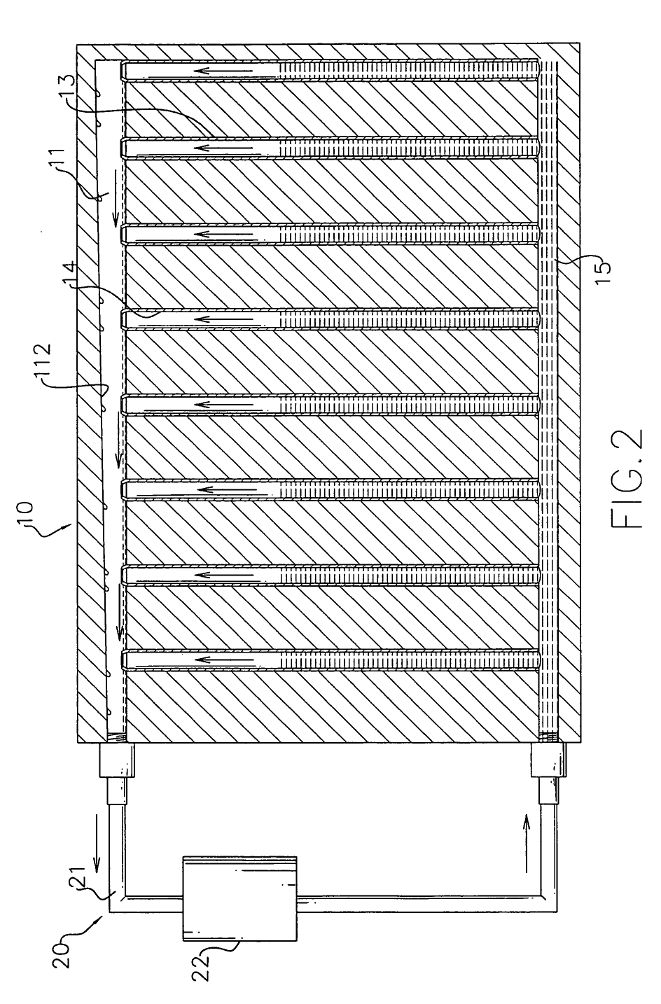

With reference to FIGS. 1 and 2, it is noted that the heat dissipator in accordance with the present invention includes a heat conductive plate (10) and a heat exchange assembly (20).

The heat conductive plate (10) has a first path (11) latitudinally defined in a top portion of the heat conductive plate (10) and having a first opening (111), a second path (12) also latitudinally defined in a bottom portion of the heat conductive plate (10) to be in communication with the first path (11) via multiple channels (13) defined between the first path (11) and the second path (12). The second path (12) has a second opening (121) in communication with the air. A tube (14) is received in each of the channels (13). It is to be noted that a free end of the tube (14) extends into the first path (11) so that a portion of the tube (14) protrudes from a bottom face defining the first path (11). It is to be noted that the first path (11) is inclined toward the first opening (111).

The heat exchange assembly (20) includes a connecting tube (21) having a first end in communication with the first opening (111) of the first path (11) and a second end in communication with the second opening (121) of the second path (12) and a fan assembly (22) mounted on the connecting tube (21) to produce air flow to the connecting tube (21).

Referring especially to FIG. 2, it is noted that a fluid (15) is received in the second path (12). When the heat dissipator of the present invention is implemented, the fluid (15) in the second path (12) after being heated from the heat generated by the monitor will gradually rise and flow to the first path (11) due to capillary effect and vaporization. That is, the tubes (14) have to be thin enough to allow the capillary attraction to work properly so that the fluid (15) will rise gradually from the second path (12) to the first path (11). Also, the vaporized fluid (15) flowing to the first path (11) where the temperature thereof is lower than that of the second path (12) is condensed to fluid again. With the help of the fan assembly (22) of the heat exchange assembly (20), excessive heat of the fluid (15) in the connecting tube (21) is dissipated and the cooled fluid (15) is flowing to the second path (12) for another cycle. The protruded free ends of the tubes (14) in the first path (11) aim at prevention of condensed fluid (15) inside the first path (11) from flowing back to the tubes (14) and the inclined first path (11) ensures that the fluid (15) in the first path (11) flows to the first opening (111).

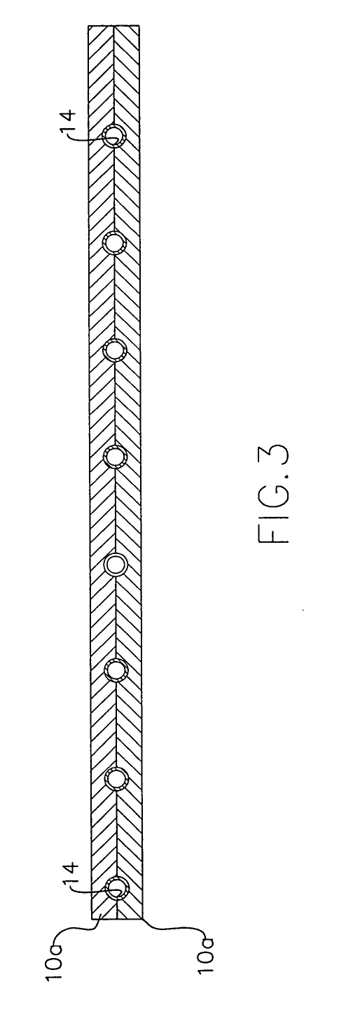

With reference to FIG. 3, it is noted that the heat conductive plate (10) is composed of two halves (10a). The tubes (14) are then sandwiched between the two halves (10a). The material for making the heat conductive plate (10) may be copper or aluminum. The fluid (15) may be water or methyl alcohol.

When the heat dissipator of the present invention is associated with a monitor (90), the heat dissipator is attached to a back (91) of the monitor (90), where the heat is mostly generated. Thus, the heat from the back (91) of the monitor (90) agitates the fluid (15) to flow upward from the second path (12) to the first path (11). Then with the assistance of the fan assembly (22) mounted on the connecting tube (21), excessive heat is dissipated. The cooled fluid (15) is then flowing back to the second path (12) for another heat dissipating cycle.

From the above description, it is noted that the heat dissipator of the present invention is able to effectively dissipate heat coming out from the back of the monitor so that the monitor is able to properly display images without worrying about images being influenced by the heat.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A monitor heat dissipator comprising:
a heat conductive plate having a first path defined in a top portion of the heat conductive plate and a second path defined in a bottom portion of the heat conductive plate to be in communication with the first path;
a fluid received in the second path to be movable to the first path; and
a heat exchange assembly having a connecting tube in communication with the first path and the second path so that excessive heat carried by the fluid which flows from the second path to the first path is dissipated by the heat exchange assembly.

2. The monitor heat dissipator as claimed in claim 1, wherein multiple channels are defined between the first path and the second path to communicate the first path with the second path and tubes are respectively received in each of the channels so that the fluid is able to flow from the second path to the first path via the tubes.

3. The monitor heat dissipator as claimed in claim 1, wherein the first path has a first opening and the second path has a second opening such that the connecting tube respectively communicates with the first path and the second path via the first opening and the second opening.

4. The monitor heat dissipator as claimed in claim 2, wherein the first path has a first opening and the second path has a second opening such that the connecting tube respectively communicates with the first path and the second path via the first opening and the second opening.

5. The monitor heat dissipator as claimed in claim 3, wherein the first path is inclined toward the first opening to ensure that the fluid in the first path is flowing to the first opening.

6. The monitor heat dissipator as claimed in claim 2, wherein free ends of the tubes in the first path extend into the first path to prevent the fluid flowing from the second path to the first path from flowing back to the tubes.

7. The monitor heat dissipator as claimed in claim 3, wherein free ends of the tubes in the first path extend into the first path to prevent the fluid flowing from the second path to the first path from flowing back to the tubes.

8. The monitor heat dissipator as claimed in claim 4, wherein free ends of the tubes in the first path extend into the first path to prevent the fluid flowing from the second path to the first path from flowing back to the tubes.

9. The monitor heat dissipator as claimed in claim 5, wherein free ends of the tubes in the first path extend into the first path to prevent the fluid flowing from the second path to the first path from flowing back to the tubes.

10. The monitor heat dissipator as claimed in claim 1, wherein the heat exchange assembly further comprises a fan assembly mounted on the connecting tube to dissipate heat of the fluid in the connecting tube.

11. The monitor heat dissipator as claimed in claim 2, wherein the heat exchange assembly further comprises a fan assembly mounted on the connecting tube to dissipate heat of the fluid in the connecting tube.

12. The monitor heat dissipator as claimed in claim 3, wherein the heat exchange assembly further comprises a fan assembly mounted on the connecting tube to dissipate heat of the fluid in the connecting tube.

13. The monitor heat dissipator as claimed in claim 4, wherein the heat exchange assembly further comprises a fan assembly mounted on the connecting tube to dissipate heat of the fluid in the connecting tube.

14. The monitor heat dissipator as claimed in claim 5, wherein the heat exchange assembly further comprises a fan assembly mounted on the connecting tube to dissipate heat of the fluid in the connecting tube.

15. The monitor heat dissipator as claimed in claim 6, wherein the heat exchange assembly further comprises a fan assembly mounted on the connecting tube to dissipate heat of the fluid in the connecting tube.

16. The monitor heat dissipator as claimed in claim 7, wherein the heat exchange assembly further comprises a fan assembly mounted on the connecting tube to dissipate heat of the fluid in the connecting tube.

17. The monitor heat dissipator as claimed in claim 8, wherein the heat exchange assembly further comprises a fan assembly mounted on the connecting tube to dissipate heat of the fluid in the connecting tube.

18. The monitor heat dissipator as claimed in claim 9, wherein the heat exchange assembly further comprises a fan assembly mounted on the connecting tube to dissipate heat of the fluid in the connecting tube.
